(19) United States
(12) Patent Application Publication
(10) Pub. No.: US 2026/0068661 A1
(43) Pub. Date: Mar. 5, 2026

(54) SEMICONDUCTOR PACKAGE AND MANUFACTURING METHOD THEREOF

(71) Applicant: Orient Semiconductor Electronics, Limited, Kaohsiung City (TW)

(72) Inventors: YUEH-MING TUNG, Kaohsiung City (TW); CHIA-MING YANG, Kaohsiung City (TW); CHIA-HUNG LIN, Kaohsiung City (TW); PIN-CHUN WANG, Kaohsiung City (TW); PO-YEN YEN, Kaohsiung City (TW)

(21) Appl. No.: 18/928,219

(22) Filed: Oct. 28, 2024

(30) Foreign Application Priority Data
Sep. 4, 2024 (TW) 113133556

(51) Int. Cl. H01L 23/367; H01L 21/48; H01L 21/56; H01L 23/00; H01L 23/31; H01L 25/16

(52) U.S. Cl. CPC H01L 23/3675

(57) ABSTRACT

The present disclosure provides a semiconductor package. The semiconductor package includes a substrate, a die, a thermally conductive material, a plurality of bonding wires, a molding compound, and a heat-dissipating frame. The substrate has opposing top and bottom surfaces. The thermally conductive material is disposed between the die and the substrate to bond the die to the top surface of the substrate. One end of each of the bonding wires is connected to the die and the other end of each of the bonding wires is connected to the top surface of the substrate. The molding compound is formed on the top surface of the substrate to cover the die and the bonding wires. The heat-dissipating frame is disposed on the top surface of the substrate to enclose the molding compound. The present disclosure further provides a method of manufacturing the above semiconductor package.

### CROSS-REFERENCE TO RELATED APPLICATIONS

The present application is based on and claims priority to Taiwanese Application Number 113133556, filed Sep. 4, 2024, the disclosure of which is hereby incorporated by reference herein in its entirety.

### FIELD OF THE DISCLOSURE

This disclosure relates to a semiconductor package and a manufacturing method thereof, and more particularly relates to a semiconductor package using a thermally conductive material, and a manufacturing method thereof.

### BACKGROUND OF THE DISCLOSURE

Currently, if there is a need for heat dissipation in semiconductor packages using wire bonding technology, heat spreaders are usually mounted on the molding compounds of the semiconductor packages. However, this method is not effective in dissipating the heat generated by the operations of the dies in the semiconductor packages.

### SUMMARY

In view of the above, the present disclosure provides a semiconductor package and a manufacturing method thereof, in which a die is bonded to a substrate in the semiconductor package using a thermally conductive material to effectively dissipate the heat generated by the operation of the die.

In one embodiment, the semiconductor package of the present disclosure includes a substrate, a die, a thermally conductive material, a plurality of bonding wires, a molding compound, and a heat-dissipating frame. The substrate has opposing top and bottom surfaces. The thermally conductive material is disposed between the die and the substrate to bond the die to the top surface of the substrate. One end of each of the bonding wires is connected to the die and the other end of each of the bonding wires is connected to the top surface of the substrate. The molding compound is formed on the top surface of the substrate to cover the die and the bonding wires. The heat-dissipating frame is disposed on the top surface of the substrate to enclose the molding compound.

In one embodiment, the method of manufacturing a semiconductor package comprises: providing a substrate having opposing top and bottom surfaces; providing a first die; disposing a thermally conductive material between the first die and the substrate to attach the first die to the top surface of the substrate; disposing a plurality of bonding wires such that one end of each of the bonding wires is connected to the first die, and the other end of each of the bonding wires is connected to the top surface of the substrate; forming a molding compound on the top surface of the substrate to cover the first die and the bonding wires; and disposing a heat-dissipating frame on the top surface of the substrate to enclose the molding compound.

The semiconductor package of the present disclosure is provided a thermally conductive material to bond a die to a substrate in the semiconductor package, which may effectively dissipate the heat generated by the operation of the die. Therefore, the semiconductor package of the present disclosure has a better heat dissipation effect.

The foregoing, as well as additional objects, features and advantages of the disclosure will be more readily apparent from the following detailed description, which proceeds with reference to the accompanying drawings.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of the semiconductor package of the present disclosure.

FIGS. 2 to 10 illustrate the method of manufacturing the semiconductor package of FIG. 1.

### DETAILED DESCRIPTION OF THE DISCLOSURE

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatial relative terms, such as “beneath. ” “below,” “lower,” “above,” “upper” and the like, may be used herein for ease of description to describe one element or feature's relationship to another element(s) or feature(s) as illustrated in the figures. The spatial relative terms are intended to encompass different orientations of the device in use or operation in addition to the orientation depicted in the figures. The apparatus may be otherwise oriented (rotated 90 degrees or at other orientations) and the spatial relative descriptors used herein may likewise be interpreted accordingly.

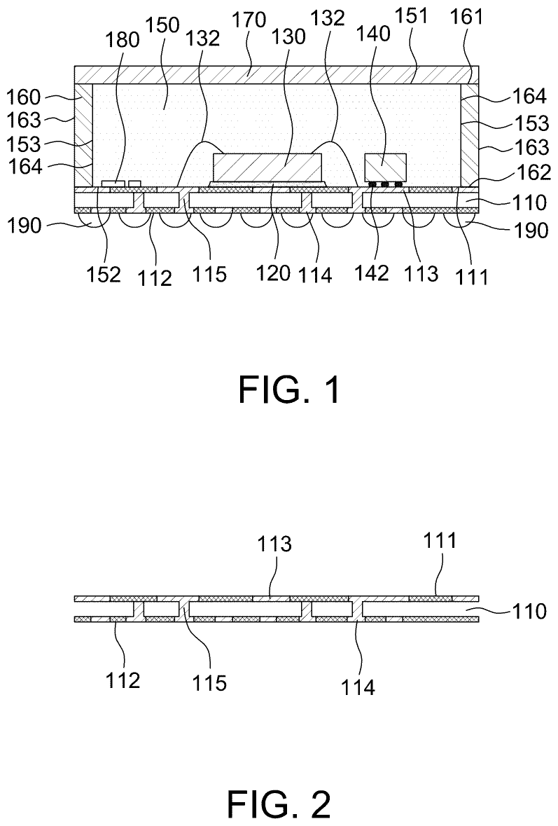

Referring to FIG. 1, the semiconductor package of the present disclosure includes a substrate 110. The substrate 110 has opposing first surface 111 and second surface 112, and the first surface 111 and the second surface 112 are located on different planes. For example, the first surface 111 is a top surface and the second surface 112 is a bottom surface, but is not limited thereto. The first surface 111 and the second surface 112 of the substrate 110 are formed with a conductive trace 113 and a conductive trace 114 thereon, respectively. The conductive traces 113 and 114 are electrically connected to each other by a plurality of conductive vias 115 penetrating the substrate 110 from the first surface 111 to the second surface 112. A plurality of passive components 180 may be mounted on the first surface 111 of the substrate 110 as desired.

In one embodiment, the substrate 110 may be a single-layer or multi-layer circuit board, a redistribution layer (RDL) substrate or a glass substrate.

At least one, for example, a plurality of dies is disposed on the first surface 111 of the substrate 110. The plurality of dies includes at least a first die 130 and a second die 140. The first die 130 and the second die 140 are disposed side by side on the substrate 110. The first die 130 and the second die 140 each have an active surface and a back surface opposite to the active surface.

The back surface of the first die 130 is attached to the first surface 111 of the substrate 110 using a thermally conductive material 120. More specifically, the thermally conductive material 120 is functioned as an adhesive to attach the first die 130 to the substrate 110. The first die 130 is electrically connected to the substrate 110 by means of a plurality of bonding wires 132, i.e., the respective ends of the bonding wires 132 are connected to the active surface of the first die 130 and the first surface 111 of the substrate 110. Therefore, the first die 130 is electrically connected to the substrate 110 through the bonding wires 132.

The second die 140 may be attached and electrically connected to the first surface 111 of the substrate 110 using flip chip technology. A plurality of conductive bumps 142 is disposed on the active surface of the second die 140. The conductive bumps 142 are disposed between the second die 140 and the substrate 110 so that the second die 140 is electrically connected to the substrate 110 through the conductive bumps 142. In another embodiment, the second die 140 may be electrically connected to the substrate 110 with bonding wires.

A molding compound 150 is formed on the first surface 111 of the substrate 110 to cover the first die 130, the second die 140, the passive components 180 and the bonding wires 132.

The molding compound 150 has a first surface 151, a second surface 152, and a plurality of third surfaces 153. The first surface 151 and the second surface 152 are located on different planes. The third surfaces 153 connect the first surface 151 and the second surface 152. In one embodiment, the first surface 151 is a top surface, the second surface 152 is a bottom surface, and the third surfaces 153 are side surfaces, but is not limited thereto. The second surface 152 of the molding compound 150 is in contact with the first surface 111 of the substrate 110.

A heat-dissipating frame 160 is disposed on the first surface 111 of the substrate 110 to surround the molding compound 150, the first die 130, the second die 140, the passive components 180 and the bonding wires 132. The heat-dissipating frame 160 has a first surface 161, a second surface 162, a plurality of third surfaces 163 and a plurality of fourth surfaces 164. The first surface 161 and the second surface 162 are located on different planes. The third surfaces 163 and the fourth surfaces 164 connect the first surface 161 and the second surface 162.

In one embodiment, the first surface 161 is a top surface, the second surface 162 is a bottom surface, the third surfaces 163 are outer surfaces, and the fourth surfaces 164 are inner surfaces. The third surfaces 163 encircle the fourth surfaces 164. The fourth surfaces 164 of the heat-dissipating frame 160 are respectively in contact with the third surfaces 153 of the molding compound 150. The first surface 161 of the heat-dissipating frame 160 is not covered by the molding compound 150.

A heat spreader 170 is provided on the first surface 151 of the molding compound 150 to be in contact with the first surface 161 of the heat-dissipating frame 160.

In addition, a plurality of solder balls 190 is disposed on the second surface 112 of the substrate 110 and electrically connected to the substrate 110. The solder balls 190 are electrically connected to the bonding wires 132 through the conductive traces 113, 114, and the conductive vias 115 on the substrate 110, so that the first die 130 may be electrically connected to an external circuit through the bonding wires 132 and the substrate 110 using the solder balls 190. Similarly, the second die 140 may be electrically connected to an external circuit through the substrate 110 using the solder balls 190.

According to the semiconductor package of the present disclosure, the heat generated by the first die 130 may be conducted to the substrate 110 through the thermally conductive material 120 and dissipated to the environment through the heat-dissipating frame 160 and the heat spreader 170.

Referring to FIGS. 2 to 10, which illustrate a method of manufacturing the semiconductor package of FIG. 1. As shown in FIG. 2, a substrate 110 is provided. The substrate 110 has opposing first surface 111 and second surface 112, and the first surface 111 and the second surface 112 are located on different planes. For example, the first surface 111 is a top surface and the second surface 112 is a bottom surface, but is not limited thereto. The first surface 111 and the second surface 112 of the substrate 110 are formed with a conductive trace 113 and a conductive trace 114 thereon, respectively. The conductive traces 113 and 114 are electrically connected to each other by a plurality of conductive vias 115 penetrating the substrate 110 from the first surface 111 to the second surface 112.

In one embodiment, the substrate 110 may be a single-layer or multi-layer circuit board, a redistribution layer (RDL) substrate or a glass substrate.

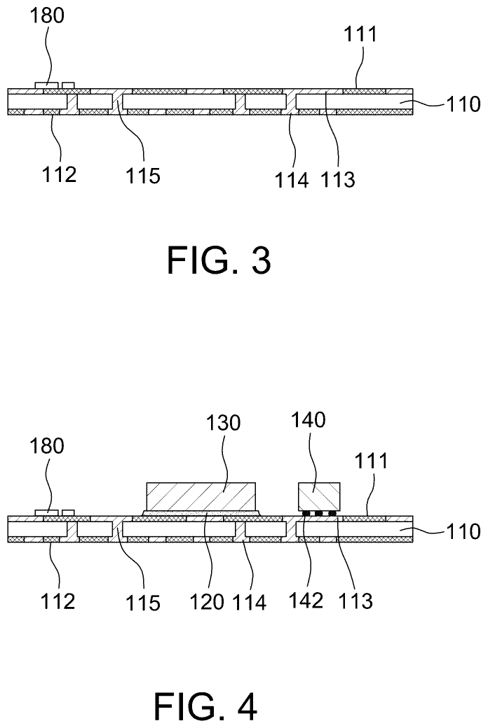

As shown in FIG. 3, a plurality of passive components 180 is then mounted on the first surface 111 of the substrate 110.

As shown in FIG. 4, at least one, for example, a plurality of dies is then disposed on the first surface 111 of the substrate 110. The plurality of dies includes at least a first die 130 and a second die 140. The first die 130 and the second die 140 are disposed side by side on the substrate 110. The first die 130 and the second die 140 each have an active surface and a back surface opposite to the active surface.

The back surface of the first die 130 is attached to the first surface 111 of the substrate 110 using a thermally conductive material 120. More specifically, the thermally conductive material 120 is functioned as an adhesive to attach the first die 130 to the substrate 110. The second die 140 may be attached and electrically connected to the first surface 111 of the substrate 110 using flip chip technology. A plurality of conductive bumps 142 is disposed on the active surface of the second die 140. The conductive bumps 142 are disposed between the second die 140 and the substrate 110 so that the second die 140 is electrically connected to the substrate 110 through the conductive bumps 142.

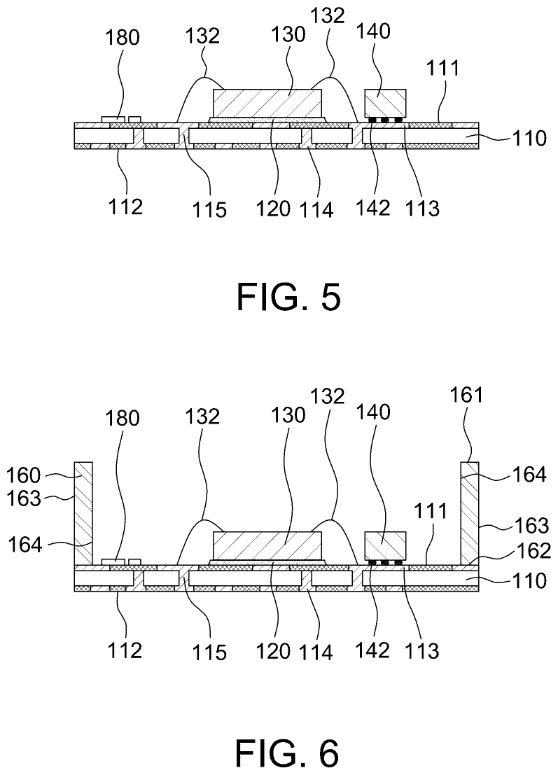

As shown in FIG. 5, the first die 130 is electrically connected to the substrate 110 by means of a plurality of bonding wires 132. The respective ends of the bonding wires 132 are connected to the active surface of the first die 130 and the first surface 111 of the substrate 110. In another embodiment, the second die 140 may be electrically connected to the substrate 110 with bonding wires.

As shown in FIG. 6, a heat-dissipating frame 160 is then disposed on the first surface 111 of the substrate 110 to surround the first die 130, the second die 140, the passive components 180 and the bonding wires 132. The heat-dissipating frame 160 has a first surface 161, a second surface 162, a plurality of third surfaces 163 and a plurality of fourth surfaces 164. The first surface 161 and the second surface 162 are located on different planes. The third surfaces 163 and the fourth surfaces 164 connect the first surface 161 and the second surface 162.

In one embodiment, the first surface 161 is a top surface, the second surface 162 is a bottom surface, the third surfaces 163 are outer surfaces, and the fourth surfaces 164 are inner surfaces. The third surfaces 163 encircle the fourth surfaces 164.

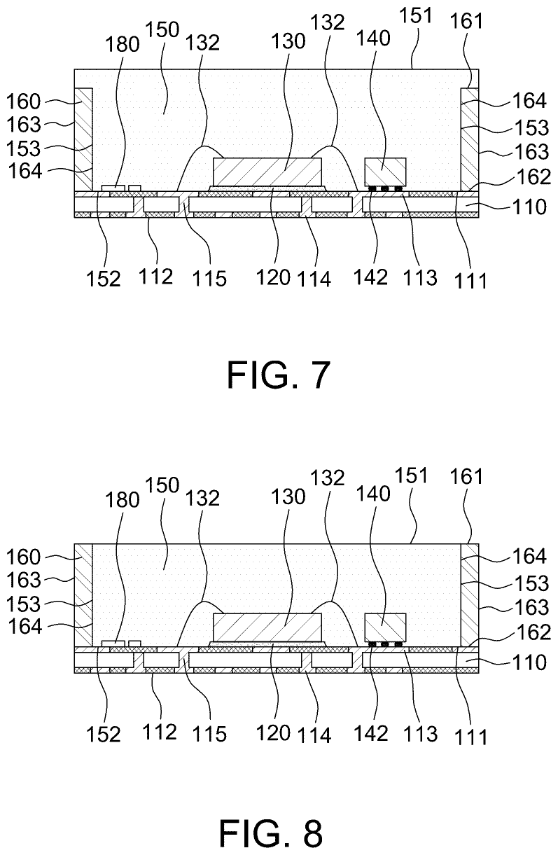

As shown in FIG. 7, a molding compound 150 is then formed on the first surface 111 of the substrate 110 to cover the first die 130, the second die 140, the passive components 180 and the bonding wires 132.

As shown in FIG. 8, a part of the molding compound 150 is then removed by grinding to expose out the first surface 161 of the heat-dissipating frame 160.

The molding compound 150, when partially removed, has a first surface 151, a second surface 152, and a plurality of third surfaces 153. The first surface 151 and the second surface 152 are located on different planes. The third surfaces 153 connect the first surface 151 and the second surface 152. In one embodiment, the first surface 151 is a top surface, the second surface 152 is a bottom surface, and the third surfaces 153 are side surfaces, but is not limited thereto.

The second surface 152 of the molding compound 150 is in contact with the first surface 111 of the substrate 110. The heat-dissipating frame 160 is disposed to surround the molding compound 150 and is in contact with the third surfaces 153 of the molding compound 150.

In another embodiment, after performing the steps shown in FIG. 6, an exposed mold may be provided such that the first surface 161 of the heat-dissipating frame 160 is exposed from the exposed mold (not shown). Afterwards, the molding compound 150 is formed on the first surface 111 of the substrate 110 with the mold. The molding compound 150 formed in this manner will not cover the first surface 161 of the heat-dissipating frame 160, and therefore there is no need to grind the molding compound 150.

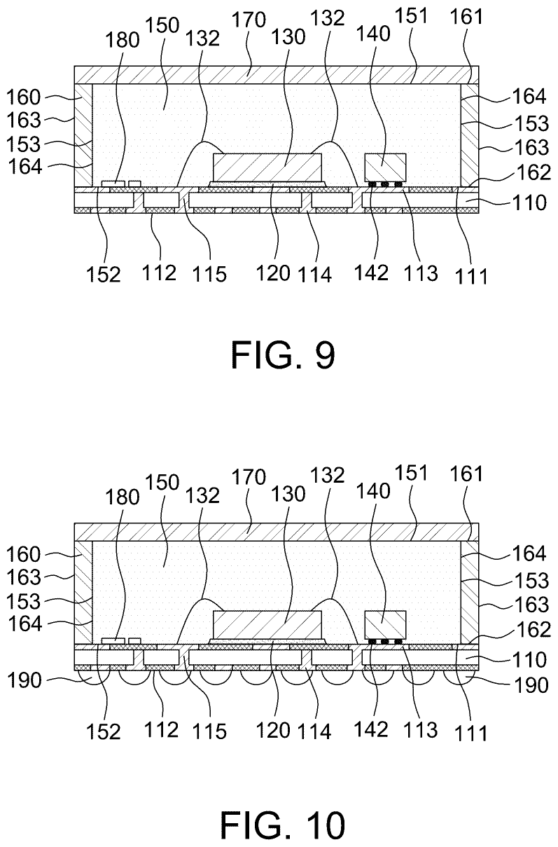

As shown in FIG. 9, a heat spreader 170 is then disposed on the first surface 151 of the molding compound 150 to be in contact with the first surface 161 of the heat-dissipating frame 160.

As shown in FIG. 10, a plurality of solder balls 190 is then disposed on the second surface 112 of the substrate 110 and electrically connected to the substrate 110 so as to form the semiconductor package of FIG. 1.

The solder balls 190 are electrically connected to the bonding wires 132 through the conductive traces 113, 114, and the conductive vias 115 on the substrate 110, so that the first die 130 may be electrically connected to an external circuit through the bonding wires 132 and the substrate 110 using the solder balls 190. Similarly, the second die 140 may be electrically connected to an external circuit through the substrate 110 using the solder balls 190.

The semiconductor package of the present disclosure is provided a thermally conductive material to bond a die to a substrate in the semiconductor package, which may effectively dissipate the heat generated by the operation of the die. Therefore, the semiconductor package of the present disclosure has a better heat dissipation effect.

The semiconductor package of the present disclosure is provided a thermally conductive material to bond a die to a substrate in the semiconductor package, which may effectively dissipate the heat generated by the operation of the die. Therefore, the semiconductor package of the present disclosure has a better heat dissipation effect.

Although the preferred embodiments of the disclosure have been disclosed for illustrative purposes, those skilled in the art will appreciate that various modifications, additions and substitutions are possible, without departing from the scope and spirit of the disclosure as disclosed in the accompanying claims.

1. A semiconductor package, comprising:
a substrate having opposing top and bottom surfaces;
a first die disposed on the top surface of the substrate;
a thermally conductive material disposed between the first die and the substrate to attach the first die to the top surface of the substrate;
a plurality of bonding wires, one end of each of the bonding wires being connected to the first die, and the other end of each of the bonding wires being connected to the top surface of the substrate;
a molding compound formed on the top surface of the substrate to cover the first die and the bonding wires; and
a heat-dissipating frame disposed on the top surface of the substrate to enclose the molding compound.

2. The semiconductor package as claimed in claim 1, further comprising:
a heat spreader disposed on the molding compound to be in contact with the heat-dissipating frame.

3. The semiconductor package as claimed in claim 1, wherein the substrate is one selected from the group consisting of circuit board, redistribution layer substrate and glass substrate.

4. The semiconductor package as claimed in claim 1, further comprising:
a second die disposed on the top surface of the substrate; and
a plurality of conductive bumps disposed between the second die and the substrate, the conductive bumps being electrically connected to the second die and the substrate,
wherein the molding compound further covers the second die.

5. A method of manufacturing a semiconductor package, comprising:
providing a substrate having opposing top and bottom surfaces;
providing a first die;
disposing a thermally conductive material between the first die and the substrate to attach the first die to the top surface of the substrate;
disposing a plurality of bonding wires such that one end of each of the bonding wires is connected to the first die, and the other end of each of the bonding wires is connected to the top surface of the substrate;
forming a molding compound on the top surface of the substrate to cover the first die and the bonding wires; and
disposing a heat-dissipating frame on the top surface of the substrate to enclose the molding compound.

6. The method as claimed in claim 5, further comprising:
disposing a heat spreader on the molding compound to be in contact with the heat-dissipating frame.

7. The method as claimed in claim 5, further comprising:
removing a part of the molding compound by grinding to expose out the heat-dissipating frame.

8. The method as claimed in claim 5, further comprising:
before forming the molding compound, providing an exposed mold such that the heat-dissipating frame is exposed from the exposed mold.

9. The method as claimed in claim 5, wherein the substrate is one selected from the group consisting of circuit board, redistribution layer substrate and glass substrate.

10. The method as claimed in claim 5, further comprising:
disposing a plurality of conductive bumps on a second die; and
disposing the second die on the top surface of the substrate such that the conductive bumps are disposed between the second die and the substrate and the conductive bumps are electrically connected to the second die and the substrate.
